(19) United States
(12) Patent Application Publication
(10) Pub. No.: US 2005/0108606 A1
(43) Pub. Date: May 19, 2005

(54) Input/output switching arrangement for semiconductor circuits, a method for testing driver circuits in semiconductor circuits

(76) Inventors: Georg Muller, Munchen (DE); Stefan Sommer, Furth (DE)

Correspondence Address: EDELL, SHAPIRO, FINNAN & LYTLE, LLC, 1901 RESEARCH BOULEVARD, SUITE 400, ROCKVILLE, MD, 20850, US

(21) Appl. No.: 10/989,384

(22) Filed: Nov. 17, 2004

(30) Foreign Application Priority Data
Nov. 17, 2003 (DE) 103 53 586.1

(51) Int. Cl. G01R 31/28

(52) U.S. Cl. 714/734

(57) ABSTRACT

A test for internal circuits in semiconductor circuits, for example DRAMs, in a reduced-I/O mode requires that contact be made only with a subset of the signal connections on the semiconductor circuit. Driver circuits associated with signal connections which are not contained in the subset are internally connected to a test potential line (TPOT), and the latter is connected to a supply potential (GND, VCC) for the semiconductor circuit or to a monitor connection (MON), so that all driver circuits can be tested or monitored under load even during a burn-in in the reduced-I/O mode. During the testing of semiconductor circuits in the reduced-I/O mode, the test coverage is increased.

### CROSS REFERENCE TO RELATED APPLICATIONS

This application claims priority under 35 USC §119 to German Application No. DE 103 53 586.1, filed on Nov. 17, 2003, and titled “Input/Output Switching Arrangement for Semiconductor Circuits, A Method for Testing Driver Circuits in Semiconductor Circuits,” the entire contents of which are hereby incorporated by reference.

### FIELD OF THE INVENTION

The invention relates to an input/output switching arrangement for semiconductor circuits and to testing driver circuits in semiconductor circuits.

### BACKGROUND

Driver circuits are used to convert internal signals in semiconductor circuits in a manner which is suitable for transmitting the internal signal to a further semiconductor circuit or to convert an external signal in a manner which is suitable for the internal processing. The driver circuits form the interface between the semiconductor circuit and the outside world.

In this context, a driver circuit may optionally be in the form of an output driver (driver), in the form of a receiver circuit (receiver) or in the form of a bidirectional circuit with output-driver and receiver-circuit functionality. The output driver drives an output signal generated by internal circuits in the semiconductor circuit onto a signal line which is connected to a signal connection on the semiconductor circuit. The receiver circuit conditions an input signal applied to the signal connection in a manner which is suitable for processing in the internal circuits.

Semiconductor circuits (subsequently also test pieces) are tested on programmable test apparatuses or component testers (ATE, automatic test equipment). The test time per semiconductor circuit is stipulated essentially by the functionality of the semiconductor circuit. To reduce the test costs, whose proportion of the total production costs in the case of DRAMs (dynamic random access memories), for example, is 15% to 20% of the total production costs, one goal is to provide a higher throughput of test pieces on the test apparatuses. To test the test pieces, the signal connections on the test pieces are connected to I/O channels or test ports on the component tester. The component tester's test ports connected to the inputs of the test piece are therefore used to output test patterns, which are read back via test ports connected to the output circuits of the test piece for the purpose of evaluation in the component tester. The test parallelism is therefore limited by the number of test ports on the component tester.

To increase the test parallelism, complex semiconductor circuits, such as DRAMs, are operated in a special test mode (reduced-I/O mode) for various time-consuming tests (memory cell tests, burn-in). In the reduced-I/O mode, the actual testing of the test piece is performed inside the test piece. To initiate the internal test by the test apparatus and to send the test result from the test piece to the test apparatus, only a subset of the signal connections on the semiconductor circuit is required.

One customary test method using a reduced-I/O mode is the boundary scan method. For the boundary scan method, a subset of the signal connections on the test piece forms a serial interface. The serial interface and shift registers which can be controlled by the serial interface are used to write test vectors, inter alia, into the input or output registers of the test piece, without this requiring direct access to the signal connection which is associated with the respective input or with the respective output of the test piece.

A further customary method for testing semiconductor memory devices such as DRAMs is the implementation of an internal self-test unit (BIST, built-in self-test). In this case, the semiconductor memory device's memory cell array is tested by the self-test unit inside the test piece. To initiate or control the internal test and to transmit the test result, contact is merely necessary with a subset of the signal connections.

German patent application 102 08 757.1-35 describes a magazine apparatus which is used for simultaneously fixing and making contact with a plurality of DRAMs at a test location in the test apparatus. The internal self-test device in the DRAM performs a self-test on a DRAM, compresses the test result and outputs the compressed test result on precisely one signal connection of the DRAM.

A drawback of known reduced-I/O test methods is the exclusion of the driver circuits from the test. For this reason, although the majority of the tests to which the test pieces are subjected is performed using a reduced-I/O test mode, additional tests are also necessary in which contact is made with all of the signal connections on the test pieces.

DE 101 38 556 C1 discloses a method for testing bidirectional driver circuits in the course of a reduced-I/O test method. To this end, a respective test signal which is output by the output driver in the bidirectional driver circuit is read back via the receiver circuit in the same driver circuit. The test signals are controlled and evaluated using boundary scan registers.

A drawback of the method in DE 101 38 556 C1 is its limitation to testing bidirectional driver circuits. The output drivers in the driver circuits are tested without a load.

### SUMMARY

The invention is therefore based on the object of providing an input/output switching arrangement which makes it possible to test semiconductor circuits driver circuits which are not connected to a test apparatus and hence also a method for testing driver circuits in semiconductor circuits in conjunction with reduced-I/O test modes. The invention also comprises a semiconductor circuit which has an input/output switching arrangement of this type and a method for testing driver circuits in semiconductor circuits.

The aforesaid objects are achieved individually and/or in combination, and it is not intended that the present invention be construed as requiring two or more of the objects to be combined unless expressly required by the claims attached hereto.

In accordance with the present invention, an input/output switching arrangement for semiconductor circuits comprises a signal connection, a driver circuit connected to the signal connection and also a connecting line between the signal connection and the driver circuit. In this arrangement, the signal connection is a contact or a contact pad on which the semiconductor circuit is supplied with a signal or on which a signal generated by the semiconductor circuit is tapped off. The driver circuit comprises an output driver, which is suitable for driving an output signal generated by internal circuits in the semiconductor circuit on a signal line which is connected to the signal connection, or comprises a receiver circuit which is suitable for conditioning an input signal applied to the signal connection, or both. There is no intervention in the time-critical signal path between the signal connection and the driver circuit.

The input/output switching arrangement also includes a switching device which can be controlled by a test mode signal and, in a test mode in the semiconductor circuit, connects the signal connection to a test potential line. Preferably, the test potential line is connected to an internal potential, for example the negative or positive supply potential in the semiconductor circuit. This advantageously allows an output driver in the input/output switching arrangement to be tested under defined stress conditions during a burn-in test, for example, by connecting the signal connection associated with the output driver to an internal potential.

Alternatively, the test potential line is advantageously connected to a monitor connection on the semiconductor circuit. In this case, the monitor connection is either an additional connection on the semiconductor circuit or a standard signal connection on the semiconductor circuit which has the functionality of a monitor connection during a test mode. This advantageously permits analog evaluation of the output signal generated by the output driver in a semiconductor circuit's reduced-I/O mode.

In one embodiment, a test signal path is produced between the signal connection and the switching device in series with the connecting line between the signal connection and the driver circuit. In this case, the test signal path is also not routed in sections via the connecting line. In addition to the driver circuits themselves, the connecting line to the signal connection is also tested.

The switching devices are preferably designed such that the voltage levels and current directions required for the test case are made possible. Preferably, the switching device is therefore in the form of a transfer gate with an n-channel transistor and a p-channel transistor which is arranged in parallel with the n-channel transistor and is actuated using the inverted test mode signal.

In accordance with another embodiment of the present invention, a semiconductor circuit comprises internal circuits which are suitable for processing and generating signals and also input/output switching arrangements with a respective signal connection for connecting a respective signal line. The signal connections are used to receive input signals which are to be processed and to output output signals generated by the internal circuits. In this case, the invention has the input/output switching arrangements in the form of input/output switching arrangements of the type described above.

Preferably, the semiconductor circuit has a selection device which allows the test potential line to be connected to one of the internal potentials and/or to a monitor connection on the basis of a test selection signal. The monitor connection is suitable for testing the receiver circuit when testing input/output switching arrangements with a receiver circuit, for example, by virtue of a test signal being fed in on the monitor connection and the receiver circuit's reaction to the test signal which is fed in being monitored.

Advantageously, the test potential lines in a respective group of input/output switching arrangements are connected to one another.

The group of input/output switching arrangements is formed, by way of example by all of the input/output switching arrangements which are not needed for conventionally testing the semiconductor circuit in a reduced-I/O mode. A group of input/output switching arrangements may alternatively be formed, by way of example, by the input/output switching arrangements with output drivers or by the input/output switching arrangements with receiver circuits or by the input/output switching arrangements with bidirectional circuits.

When testing the output drivers in the course of a burn-in test, for example, all of the output drivers may simultaneously be subjected to defined stress conditions by respectively driving them against a defined potential. This also relates to the output drivers in bidirectional driver circuits, which means that the invention may involve bidirectional driver circuits being tested with greater test definition than on the basis of the prior art described at the outset.

To test an individual output driver using the monitor connection, the respective other output drivers are preferably connected to a high impedance.

Preferably, the switching devices can be switched independently of one another individually or in groups. As a result, when testing receiver circuits, for example, the circuits may be assigned defined input signals independently of one another.

The inventive input/output switching arrangement permits an advantageous method for testing semiconductor circuits in reduced-I/O mode. In this case, the semiconductor circuits have a plurality of input/output switching arrangements, which have a respective signal connection, and also internal circuits connected to the input/output switching arrangements. In the case of a test method which uses a reduced-I/O mode, a respective genuine subset of the signal connections is connected to a test apparatus. The internal circuits are tested internally using the genuine subset of the signal connections.

In line with the invention, the signal connections which are not contained in the genuine subset are connected to an internal test potential line on the basis of a test signal generated in the test mode and are tested using the internal test potential line. This method thus permits full test coverage for a functionality of the semiconductor circuit for a reduced-I/O test method. The entire component test can be carried out on test apparatuses for the reduced-I/O mode with a high level of test parallelism. Subsequent testing of the signal connections which are not covered by the reduced-I/O mode on component testers with a large number of pins is dispensed with.

Advantageously, the test potential line is connected, in the course of the test, to at least one internal potential, for example to the negative or positive supply potential in a semiconductor circuit. The driver circuits designed as output drivers or bidirectional circuits are consequently tested by connecting them to the internal test potential line and driving them against the internal potential during the test. Particularly in connection with burn-in tests, the output drivers or the output drivers of bidirectional circuits can thus be burnt in on a defined basis and their failure rate in the field can be reduced.

In accordance with a further preferred embodiment of the invention, the test potential line is connected at least intermittently to a monitor connection in the course of the test. Apart from the respective output driver which is to be tested, the remaining output drivers are connected to a high impedance. The output driver to be tested is tested by means of analog evaluation of an output signal which is output on the monitor connection by the output driver using a suitable test system. In this way, the output impedance of the output driver can be verified.

In accordance with still another embodiment of the invention, the receiver circuits are tested by connecting them individually or in groups to a monitor connection on the semiconductor circuit via the test potential line. On the monitor connection, a test signal is fed in and the receiver circuits are tested individually or in succession by virtue of a specific reaction by the semiconductor circuit to the test signal.

The above and still further objects, features and advantages of the present invention will become apparent upon consideration of the following detailed description of specific embodiments thereof, particularly when taken in conjunction with the accompanying drawings wherein like reference numerals in the figures are utilized to designate like components.

### BRIEF DESCRIPTION OF THE DRAWINGS

FIG. 1 shows a simplified circuit diagram of a semiconductor circuit with conventional input/output switching arrangements;

FIG. 2 shows a simplified circuit diagram of a semiconductor circuit with input/output switching arrangements in accordance with an exemplary embodiment of the present invention;

FIG. 3 shows a simplified circuit diagram of a semiconductor circuit with input/output switching arrangements in accordance with a second exemplary embodiment of the present invention; and

FIG. 4 shows a simplified circuit diagram of a semiconductor circuit with input/output switching arrangements with transfer gates in accordance with a third exemplary embodiment of the invention.

### DETAILED DESCRIPTION

The semiconductor circuit 4 comprises internal circuits 9 and input/output switching arrangements 10′. The input/output switching arrangements 10′ for their part respectively comprise a signal connection 1 and a driver circuit 2 which is connected to the respective associated signal connection 1 via a connecting line 3. The input/output switching arrangements 10′ are connected to the internal circuits 9 and optionally comprise an output driver (driver) 22 or a receiver circuit (receiver) 23 or a bidirectional circuit 21, which for its part is formed from a receiver circuit 23 and an output driver 22. The output drivers 22 convert a signal generated by internal circuits 9 for the purpose of output to the signal connections 1. The receiver circuits 23 respectively convert an input signal received on a signal connection 1 in a manner which is suitable for forwarding to the internal circuits 9.

When testing the internal circuits 9 in a reduced-I/O test method, contact is made only with a portion of the signal connections 1, which means that the reduced-I/O test method tests only the driver circuits 2 which are connected to these signal connections 1.

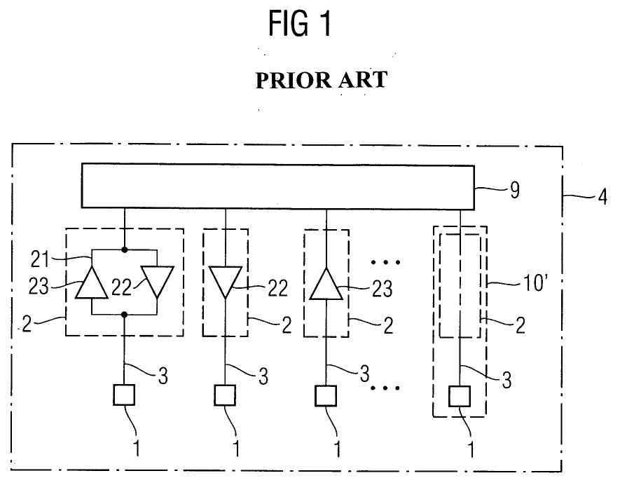

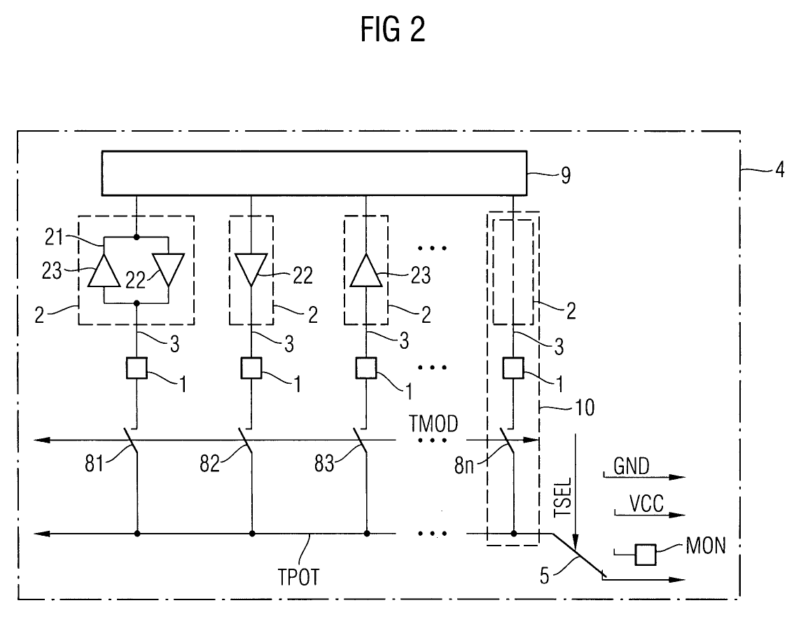

The semiconductor circuit 4 shown in FIG. 2, which is based on a first exemplary embodiment of the invention, includes internal circuits 9 and input/output switching arrangements 10 connected to the internal circuits 9, in line with FIG. 1. Besides a signal connection 1 and a driver circuit 2 which is connected to the signal connection 1 via a connecting line 3, the input/output switching arrangement 10 has a switching device 81, 82, 83, . . . , 8n. The switching device 81, 82, 83, . . . , 8n is used to connect a respective one of the signal connections 1 to a test potential line TPOT on the basis of a test mode signal TMOD. In this case, the signal connection 1 is connected to the test potential line TPOT via the switching device 81, 82, 83, . . . , 8n during a test mode. Outside of the test mode, in a normal or operating mode of the semiconductor circuit 4, the switching device 81, 82, 83, . . . , 8n is open.

The test potential line TPOT can be connected by means of a selection device 5 to a negative supply potential GND for the semiconductor circuit 4, to a positive supply potential VCC or to a monitor connection MON. The selection device 5 is controlled using a test selection signal TSEL.

To burn in the output drivers 22 in a defined fashion, the output drivers 22, for example, are now connected to the test signal line TPOT by means of the switching devices 81, 82, 83, . . . , 8n. The test signal line TPOT is connected to one of the internal supply potentials GND, VCC for the semiconductor circuit 4 by means of the selection device 5. During a burn-in operation, the output drivers accordingly drive against a defined potential.

To test the functionality of the output drivers, the output drivers 22 are connected, for example by means of the switching devices 81, 82, to the test signal line TPOT and the test signal line TPOT is connected to the monitor connection MON by means of the selection switch 5. A measurement instrument suitable for qualifying the output drivers 22 is connected to the monitor connection MON, or a suitable test channel in the test apparatus. With the exception of the output driver 22 which is currently to be tested, all of the remaining output drivers 22 are connected to a high impedance in the usual manner. The respective output signal from one of the output drivers 22 can be detected on the monitor connection MON. The multiplex function of the switching devices 81, 82, 83, . . . , 8n connected in parallel tests a plurality of output drivers 22 using a single monitor connection MON. This test can be carried out, by way of example, in parallel with an internal test in the semiconductor circuit, for example a memory cell test, and the test parallelism on a test apparatus can be increased as a result.

To test the receiver circuits 23, the receiver circuits 23 are connected to the test potential line TPOT by means of the respective associated switching devices 81, 83 and have a defined input signal applied to them via the selection device 5 and either the supply potentials GND, VCC for the semiconductor circuit 4 or via the monitor connection MON and a test apparatus test channel connected to the monitor connection.

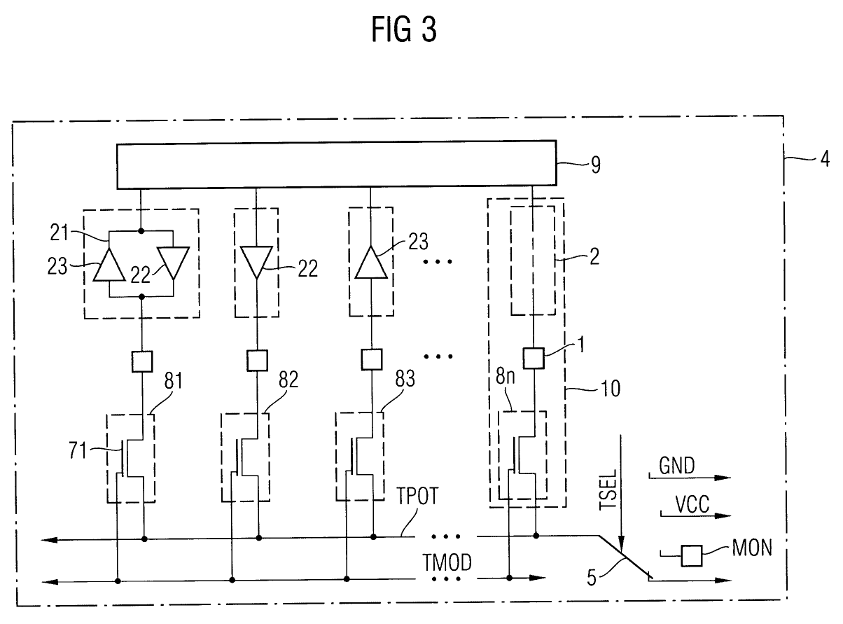

In the exemplary embodiment shown in FIG. 3, the switching devices 81, 82, 83, . . . , 8n are respectively in the form of transistor devices 71.

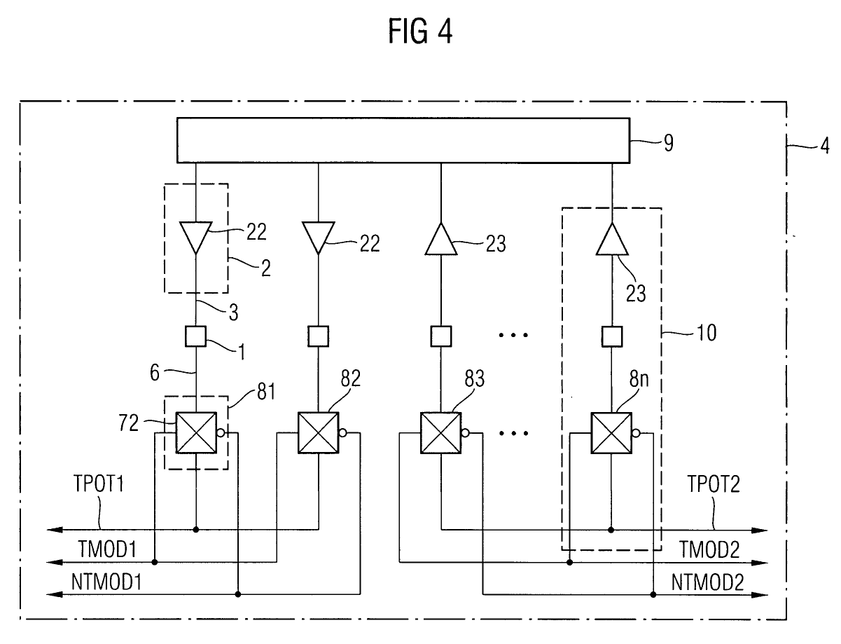

The exemplary embodiment shown in FIG. 4 differs from the preceding one firstly by virtue of the design of the switching devices 81, 82, 83, . . . , 8n as transfer gates.

In this case, each transfer gate comprises an n-channel transistor and a p-channel transistor, which is connected in parallel with the n-channel transistor and is actuated using the inverted test mode signal NTMOD.

This exemplary embodiment also respectively combines the output drivers 22 and the receiver circuits 23 into groups which have respective associated first TPOT1 and second TPOT2 test signal lines. In this exemplary embodiment, the transfer gates 72 associated with the respective groups are controlled by a first TMOD1 and a second TMOD2 test mode signal. To actuate the transfer gates 72, the respective inverted test mode signal NTMOD1, NTMOD2 is normally also required. Alternatively, the transfer gates 72 associated with the various groups may be actuated by a common test mode signal TMOD. It is likewise possible for the groups to be actuated using various test mode signals TMODn and in this case for a common test signal line TPOT to be provided, however.

FIG. 4 also schematically shows the course of a test signal path 6 between a signal connection 1 and the associated switching device 81, respectively. In this case, the test signal path 6 is arranged in series with the connecting line 3 between the signal connection and the driver circuit 2. The test signal path 6 is routed via a designated line to the signal connection 1 and does not overlap a signal path between the signal connection 1 and the driver circuit 2. As a result, the connecting line 3 is also tested at the same time and any influence on the time-critical signal path between the signal connection 1 and the driver circuit 2 is minimized.

While the invention has been described in detail and with reference to specific embodiments thereof, it will be apparent to one skilled in the art that various changes and modifications can be made therein without departing from the spirit and scope thereof. Accordingly, it is intended that the present invention covers the modifications and variations of this invention provided they come within the scope of the appended claims and their equivalents.

Reference Symbols

1 Signal connection
2 Driver circuit
21 Bidirectional driver circuit
22 Output driver
23 Receiver circuit
3 Connecting line
4 Semiconductor circuit
5 Selection device
6 Test signal path
71 Transistor device
72 Transfer gate
81 First switching device
82 Second switching device
83 Third switching device
8n nth switching device
9 Internal circuit
10 Input/output switching arrangement
10′ Input/output switching arrangement
GND Negative supply potential
MON Monitor connection
TMOD Test mode signal
NTMOD Inverted test mode signal
TMOD1 First test mode signal
TMOD2 Second test mode signal
TPOT Test potential
TPOT1 First test potential
TPOT2 Second test potential
TSEL Test selection signal
VCC Positive supply potential

1. An input/output switching arrangement for semiconductor circuits comprising:
a signal connection;
a driver circuit connected to the signal connection and comprising at least one of an output driver that drives an output signal generated by internal circuits in the semiconductor circuit on a line connected to the signal connection and a receiver circuit that conditions an input signal applied to the signal connection; and
a switching device that is controlled by a test mode signal (TMOD) and, in a test mode in the semiconductor circuit, connects the signal connection to a test potential line (TPOT).

2. The input/output switching arrangement of claim 1, wherein the test potential line (TPOT) is connected to an internal supply potential in the semiconductor circuit.

3. The input/output switching arrangement of claim 1, wherein the test potential line (TPOT) is connected to a monitor connection (MON) on the semiconductor circuit.

4. The input/output switching arrangement of claim 1, wherein a test signal path between the signal connection and the switching device is produced in series with a connecting line.

5. The input/output switching arrangement of claim 1, wherein the switching device comprises a transfer gate including an n-channel transistor and a p-channel transistor arranged in parallel with the n-channel transistor, the transfer gate being actuated using an inverted test mode signal (NTMOD).

6. A semiconductor circuit comprising:
internal circuits for processing and generating signals; and
a plurality of input/output switching arrangements as recited in claim 1, wherein each of the input/output switching arrangements includes a signal connection for receiving signals to be processed and/or for outputting generated signals.

7. The semiconductor circuit of claim 6, wherein a selection device connects the test potential line (TPOT) to an internal supply potential and/or to a monitor connection (MON) on the basis of a test selection signal (TSEL).

8. The semiconductor circuit of claim 6, wherein a respective group of homogeneous input/output switching arrangements are connected to one another via the test potential line (TPOT).

9. The semiconductor circuit of claim 6, wherein the switching devices are switchable independently of one another.

10. A method for testing a semiconductor circuit including input/output switching arrangements, which include a plurality of signal connections, and internal circuits which are connected to the input/output switching arrangements, comprising:
connecting a respective genuine subset of the signal connections to a test apparatus; and
testing the internal circuits in a test mode using the genuine subset of the signal connections;
connecting signal connections that are not contained in the genuine subset to an internal test potential line (TPOT) on the basis of a test signal (TMOD) generated in the test mode; and
testing the signal connections that are not contained in the genuine subset using the internal test potential line (TPOT).

11. The method of claim 10, further comprising:
connecting the test potential line (TPOT) to an internal supply potential in the semiconductor circuit; and
connecting driver circuits of the input/output switching arrangements to the test potential line (TPOT) in the test mode, wherein the driver circuits comprise output drivers or bidirectional circuits that are tested and/or burned in by driving against the internal supply potential.

12. The method of claim 10, further comprising:
connecting the test potential line (TPOT) to a monitor connection (MON);
connecting output drivers of the input/output switching arrangements to a high impedance apart from a respective output driver of the input/output switching arrangements that is to be tested, wherein the respective output driver is tested by analog evaluation of an output signal from at least one of the output drivers connected to the high impedance that is output on the monitor connection (MON).

13. The method of claim 10, further comprising:
connecting the test potential line (TPOT) to a monitor connection (MON);
feeding a test signal to the monitor connection; and
testing receiver circuits of the input/output switching arrangements individually or in succession by monitoring a response of the semiconductor circuit to the test signal.
